(19) United States
(12) Patent Application Publication
(10) Pub. No.: US 2015/0263059 A1
(43) Pub. Date: Sep. 17, 2015

(54) SOLID-STATE IMAGING DEVICE

(71) Applicant: Kabushiki Kaisha Toshiba, Tokyo (JP)

(72) Inventor: Soichiro UENO, Oota Tokyo (JP)

(21) Appl. No.: 14/635,883

(22) Filed: Mar. 2, 2015

(30) Foreign Application Priority Data
Mar. 14, 2014 (JP) 2014-051712

(51) Int. Cl. H01L 27/146

(52) U.S. Cl. CPC H01L 27/14645; H01L 27/14621; H01L 27/14627; H01L 27/14629; H01L 27/14685

(57) ABSTRACT

Solid-state imaging device includes a photodiode in a semiconductor substrate. A color filter aligned with the photodiode on the substrate. A first reflection layer is formed on the color filter to include a concave curved surface. A transparent supporting layer is formed on the curved surface and second reflection layer is formed on the supporting layer at a position corresponding to a focal point of the concave curved surface. A planarization layer is formed on the second reflection layer and the first reflection layer. A microlens is formed on the planarization layer. The supporting layer and the planarization layer can be formed of a same resin material. The first and second reflection layers are made of materials that have a refractive index higher than a refractive index of the resin material.

### CROSS-REFERENCE TO RELATED APPLICATION

This application is based upon and claims the benefit of priority from Japanese Patent Application No. 2014-051712, filed Mar. 14, 2014, the entire contents of which are incorporated herein by reference.

### FIELD

Embodiments described herein relate generally to a solid-state imaging device.

### BACKGROUND

The solid-state imaging device in the related art includes a plurality of pixels on which a light receiving unit, a color filter unit, and a micro lens are laminated, and the plurality of pixels are disposed in a lattice array.

When light is incident on the solid-state imaging device in the related art from a diagonal direction pixel sensitivity deteriorates, and further, a color mixture is generated.

In addition, when an interference-type filter or a prism is used as the color filter unit, spectral characteristics of the color filter unit depend on an incident angle of the light onto the color filter unit. For this reason, when the light is incident on the solid-state imaging device from the diagonal direction, and thus, when the light is incident on the color filter unit at an incident angle other than a intended angle, light having a different wavelength from a intended wavelength may pass through the color filter and the spectral characteristics of solid-state imaging device deteriorate.

In the solid-state imaging device in the related art, in order to suppress deterioration of pixel sensitivity, generation of color mixture, and deterioration of the spectral characteristics due to the color filter unit, it is required that the light be incident on the light receiving unit and the color filter unit at desired set angle (for example, a vertical angle). However, since light is generally incident on a plurality of pixels included in the solid-state imaging device light will be incident on the individual pixels at various angles, it is not easy to cause the light to be incident on the light receiving unit and the color filter unit at the desired angle for every pixels.

### DESCRIPTION OF THE DRAWINGS

FIG. 1 is a plan view illustrating a part of a solid-state imaging device according to a first embodiment.

FIG. 2 is a partial cross-sectional view of the solid-state imaging device illustrating a view along a line X-X′ in FIG. 1.

FIG. 3 to FIG. 6 are cross-sectional views corresponding to FIG. 2, illustrating a manufacturing method of the solid-state imaging device according to the first embodiment.

FIGS. 7A and 7B are diagrams illustrating light incident on the solid-state imaging device according to the first embodiment. FIG. 7A illustrates vertically incident light. FIG. 7B illustrates a diagonally incident light.

### DETAILED DESCRIPTION

In general, according to one embodiment, a solid-state imaging device includes: a semiconductor substrate that is provided with a light receiving unit (e.g., photodiode); a spectral unit (e.g., color filter); a first reflection layer; a supporting layer; and a second reflection layer. The spectral unit is provided on the light receiving unit on a first surface of the semiconductor substrate, and allows light within predetermined wavelength band to penetrate (pass). The first reflection layer includes a curved unit (e.g., concave curved surface) provided on the spectral unit. The supporting layer is provided on a front surface of the curved unit of the first reflection layer. The supporting layer is substantially transparent to light within the predetermined wavelength band. The second reflection layer is provided on the supporting layer, for example, at a position corresponding to a focal point of the curved unit. The second reflection layer may, for example, include a convex surface facing the first reflection layer.

Hereinafter, a solid-state imaging device according to an example embodiment will be described with reference to the drawings.

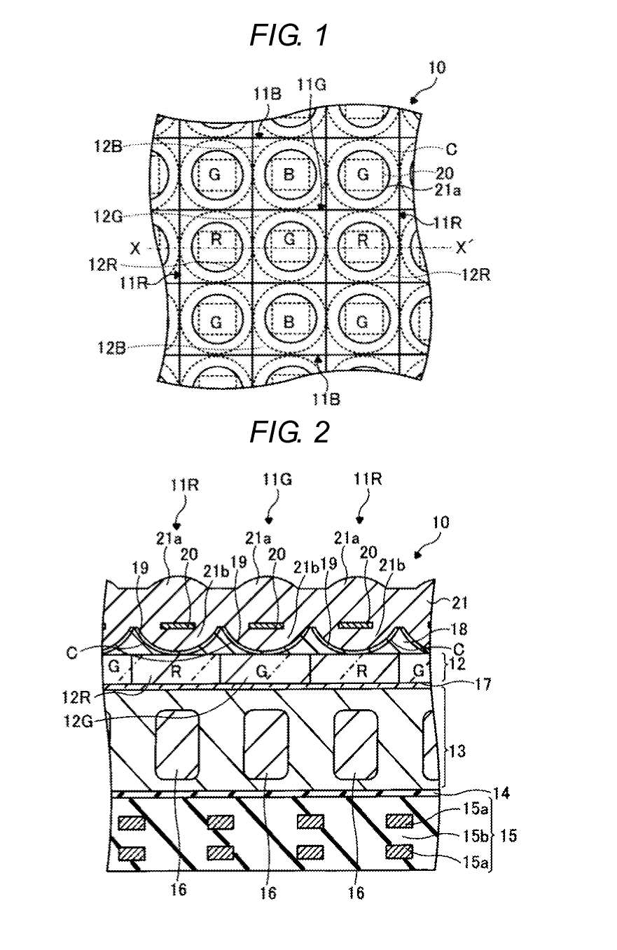

FIG. 1 is a plan view illustrating a part of the solid-state imaging device according to a first embodiment. As illustrated in FIG. 1, a solid-state imaging device 10 is a device in which a plurality of pixels is disposed in a lattice shape. The plurality of pixels is made of any of a blue pixel 11B, which receives blue light, a green pixel 11G, which receives green light, and a red pixel 11R, which receives red light. The plurality of pixels 11B, 11G, and 11R are provided to be a Bayer array, for example.

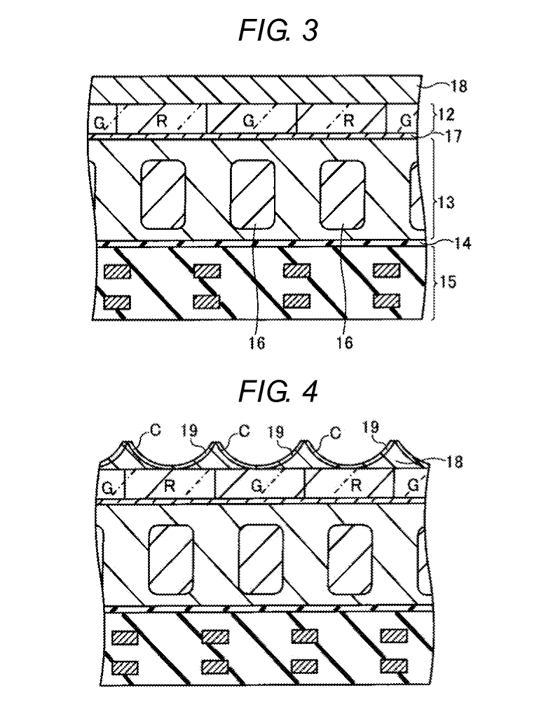

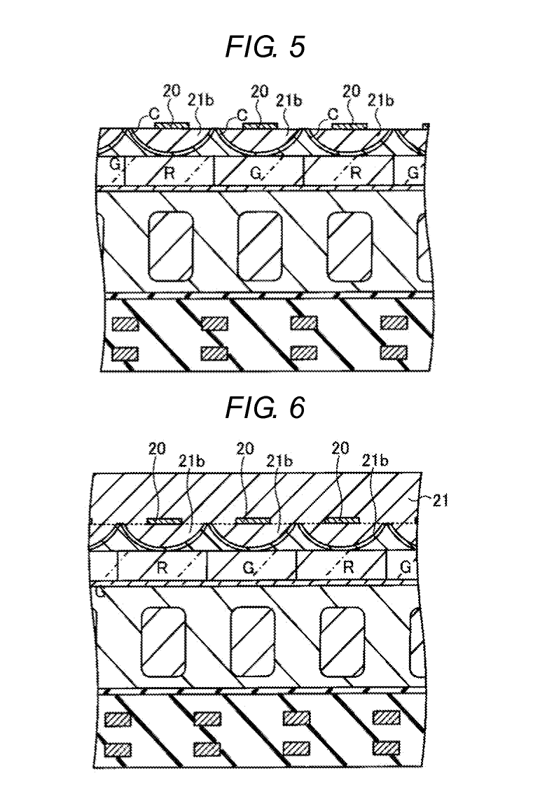

FIG. 2 is a partial cross-sectional view of the solid-state imaging device illustrating a view along line X-X′ in FIG. 1. As illustrated in FIG. 2, the solid-state imaging device 10 is a so-called “rear surface irradiation type solid-state imaging device” which includes a color filter layer 12 as a spectral layer on a rear surface (a first surface) of a semiconductor substrate 13, and includes a wiring layer 15 via an insulation film 14 on a front surface (a second surface) of the semiconductor substrate 13. That is, in the solid-state imaging device 10, the wiring layer 15 is on an opposite side of the semiconductor substrate 13 from the color filter layer 12. In addition, the wiring layer 15 is a layer in which a plurality of wiring layers is included. The plurality of wiring layers in wiring layer 15 includes a wiring 15a that is connected to a gate transistor (not specifically depicted) or the like used for reading out an electric charge generated in a light receiving unit 16 (see FIG. 3). Wirings 15a are insulated from each other by an interlayer insulation film 15b.

In the solid-state imaging device 10, a plurality of light receiving units 16 is provided in (or otherwise formed on) the semiconductor substrate 13. For example, each light receiving unit 16 is a photodiode layer which is formed by injecting impurities into the semiconductor substrate 13. The light receiving units 16 are respectively provided for every pixel illustrated in FIG. 1. Therefore, the plurality of light receiving units 16 is formed to be disposed in a lattice shape according to a disposition of the plurality of pixels 11B, 11G, and 11R.

On the rear surface of the semiconductor substrate 13 which includes the plurality of light receiving units 16, a first planarization layer 17 is provided. For example, the first planarization layer 17 is provided. The first planarization layer 17 is made of a transparent resin layer through which at least visible light can penetrate. The first planarization layer 17 is provided to mitigate roughness of the rear surface of the semiconductor substrate 13 to make the rear surface more planarized (flat).

On the upper surface of the first planarization layer 17, the color filter layer 12 (a spectral layer) is formed. The color filter layer 12 has different types of spectral units having transmission wavelength bands different from each other. For example, the spectral units are a blue color filter unit 12B, a green color filter unit 12G, and/or a red color filter unit 12R.

For example, each of the color filter units 12B, 12G, and 12R is respectively formed by mixing a predetermined pigment or dye into a transparent resin that can be patterned. The inclusion of pigments or dyes controls an absorbance of light of the color filter unit to determine the transmission band.

As illustrated above, a color filter units 12B, 12G, and 12R are respectively included each of the pixels 11B, 11G, and 11R. Therefore, in the color filter layer 12, the above-described plurality of color filter units 12B, 12G, and 12R is disposed in a lattice shape and in a Bayer array corresponding to the array of pixels.

The spectral unit may be a unit in which spectral characteristics (e.g., transmission band) are changed depending on an incident angle of light onto the spectral unit, like an interference type filter or a prism. In addition, the spectral unit need not be in the Bayer array, which is made of the red color filter, the green color filter, and the blue color filter, but may comprise a plurality of different filter elements disposed in a periodic pattern with the different filter elements absorbing, reflecting, or passing different wavelengths of light. For example, the spectral unit may comprise nine different filter elements in a regular array.

On the upper surface of the color filter layer 12, a first reflection layer 18 including a plurality of curved units C is provided. Each curved unit C is in a substantially circular shape (see FIG. 1) in a cross section plane (hereinafter, referred to as a horizontal cross section) parallel to the rear surface the semiconductor substrate 13, and is in a recessed shape (see FIG. 2) in a cross section plane which is orthogonal (hereinafter, referred to as a vertical cross section) to the rear surface of the semiconductor substrate 13. The curved units C are respectively provided for every pixel so that a curved unit C is disposed above each light receiving unit 16. Therefore, the plurality of curved units C is disposed in a lattice shape corresponding to the disposition of the plurality of pixels 11B, 11G, and 11R.

The first reflection layer 18 reflects the light which reaches the upper surface of the curved unit C towards a focal point that is defined by a curvature of the upper surface of the curved unit C. The first reflection layer 18 is formed of a material such as a metal like copper or aluminum. In addition, for example, when the first reflection layer 18 is made of copper (Cu), a coating layer 19 may be provided on the upper surface of the curved unit C as illustrated in FIG. 2. When the first reflection layer 18 is made of aluminum (Al), the coating layer 19 may not be provided.

Above the first reflection layer 18, a plurality of second reflection layers 20 is provided. Each of second reflection layers 20 is in a flat plate shape of a substantially rectangular shape (see FIG. 1) in the horizontal cross section. A second reflection layer 20 is respectively provided for every pixel. Therefore, the plurality of second reflection layers is disposed in a lattice shape corresponding to the disposition of the plurality of pixels 11B, 11G, and 11R.

The second reflection layer 20 reflects the light reflected by the upper surface of the curved unit C towards the light receiving units 16, and is configured of a reflective material.

In the first embodiment, the second reflection layer 20 has a flat plate shape but may also incorporate other shapes such as a convex surface or an angled surface, and the light reflected from the second reflection layer 20 is reflected in a direction determined by the incident angle of the light on the surface of the second reflection layer 20. Furthermore, in the first embodiment, the second reflection layer 20 is provided so that the rear surface of the second reflection layer 20 and the rear surface of the semiconductor substrate 13 are substantially parallel to each other. When the second reflection layer 20 is provided in this manner, the light reflected by the second reflection layer 20 can be vertically incident on the upper surface of the color filter layer 12 and the upper surface of the light receiving unit 16.

When the color filter layer 12 has a configuration in which the spectral characteristics change depending on the incident angle like the interference type filter or the prism, the angle of the second reflection layer 20 can be adjusted, to cause the light to be incident on the color filter layer 12 at a desired angle.

In addition, as a position of the second reflection layer 20 can be adjusted according to the transmission wavelength of the color filter unit in the pixel which includes the layer 20, it is possible to improve the spectral characteristics of the pixel. For example, when the pixel including the second reflection layer 20 is the green pixel 11G, as the second reflection layer 20 is provided at a position which coincides with the focal point of the light of green wavelength of the curved unit C of the first reflection layer 18, it is possible to further improve the spectral characteristics.

In addition, as noted the second reflection layer 20 is not necessarily a flat plate shape, and may be a layer which can reflect the light reflected in the curved unit C of the first reflection layer 18 in a desired direction. For example, second reflection layer 20 may incorporate a convex surface facing the first reflection layer 18.

On the front surface of the first reflection layer 18, the second planarization layer 21 which is made of the transparent resin layer that can cause at least the visible light to be penetrated is provided to surround the second reflection layer 20.

On the front surface of the second planarization layer 21, a projection unit 21a in a projected shape is formed at a position corresponding to the above of the light receiving unit 16. The projection unit 21a condenses the light which is incident on the solid-state imaging device 10. At the same time, for example, the projection unit 21a suppresses interference of the light which is incident on the second planarization layer 21 on the inside of the second planarization layer 21 and formation of an interference fringe. In addition, the projection unit 21a is not necessarily to be formed.

On the second planarization layer 21, a part between a part above the front surface of the curved unit C of the first reflection layer 18 and the second reflection layer 20 is a supporting layer 21b which supports the second reflection layer 20 from below for disposing the second reflection layer 20 at a desired position at a desired angle.

Next, a manufacturing method of the solid-state imaging device 10 according to the above-described embodiment will be described with reference to FIGS. 3 to 6. FIGS. 3 to 6 are respectively cross-sectional views corresponding to FIG. 2, for illustrating the manufacturing method of the solid-state imaging device 10 according to the embodiment. In addition, in the manufacturing method of the solid-state imaging device 10 according to the embodiment, processes of forming the wiring layer 15 on the rear surface of the semiconductor substrate 13 and forming the color filter layer 12 on the front surface of the semiconductor substrate 13 may be a general manufacturing method, and will be omitted in the following description.

As illustrated in FIG. 3, the wiring layer 15 is formed on the front surface which is the second surface of the semiconductor substrate 13 that has the plurality of light receiving units 16 via the insulation film 14, the color filter layer 12 is formed on the rear surface which is the first surface of the semiconductor substrate 13 via the first planarization layer 17, and the first reflection layer 18 is formed on the front surface of the color filter layer 12. The first reflection layer 18 is formed of metal, such as Cu or Al, or a material which has a refractive index different from that of the second planarization layer 21 that will be described later. The first reflection layer 18 may incorporate a hole therein that is between the second reflection layer 20 and the light receiving unit 16. Light incident on the second reflection layer 20 may pass through the hole in the first reflection layer 18 to be incident on the light receiving unit 16 below.

Next, as illustrated in FIG. 4, on the front surface of the first reflection layer 18, the curved unit C is formed for every pixel. The plurality of curved units C may be formed by patterning by using the grating mask having a light transmissivity that is different at each location, and may be formed by using an imprinting method. In addition, after this process, the coating layer 19 may be provided on the front surface of the curved unit C as necessary.

Next, as illustrated in FIG. 5, the supporting layer 21b which is a part of the second planarization layer 21 is formed to fill at least the curved unit C, and the second reflection layer 20 in a plate shape is formed on the front surface of the supporting layer 21b. The second reflection layer 20 is also formed of metal, such as Cu or Al, or a material which has a refractive index different from that of the second planarization layer 21.

Next, as illustrated in FIG. 6, on the supporting layer 21b which supports the second reflection layer 20, the transparent resin layer which is the same as the supporting layer 21b is laminated to cover the second reflection layer 20, and the second planarization layer 21 is formed. Furthermore, as necessary, a part of the front surface of the second planarization layer 21 is processed to include and a plurality of protruding units 21a (see FIG. 2).

In this manner, it is possible to manufacture the solid-state imaging device 10 illustrated in FIGS. 1 and 2.

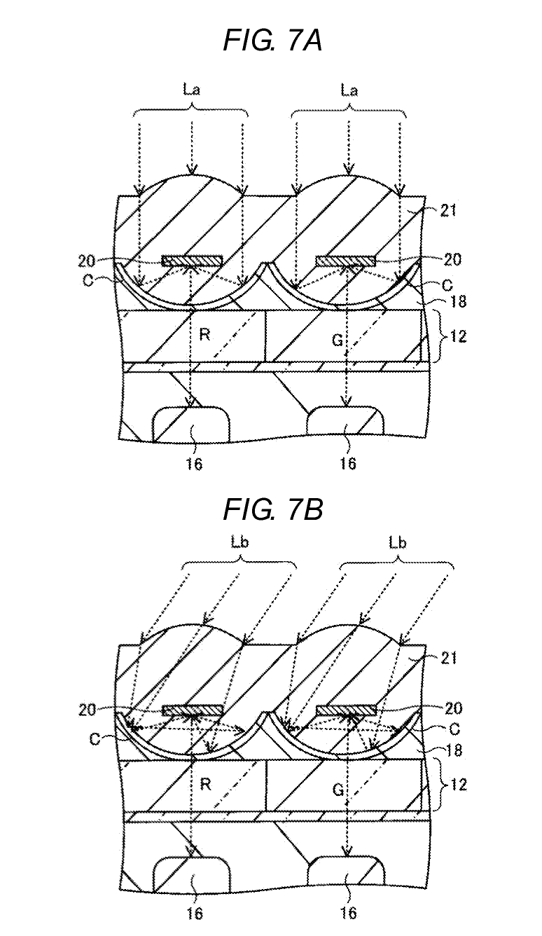

FIGS. 7A and 7B are diagrams illustrating a state where the light which is incident on the solid-state imaging device 10. FIG. 7A illustrates a vertically incident (normal to the plane of substrate 13) light on the solid-state imaging device 10. FIG. 7B illustrates diagonally incident light (obliquely incident light) on the solid-state imaging device 10.

As illustrated in FIG. 7A, when light La is incident on the second planarization layer 21 from the vertical direction, the light La travels through the second planarization layer 21 in the vertical direction, and reaches the curved unit C of the first reflection layer 18.

The light La which reaches the curved unit C is reflected on the upper surface of the curved unit C towards the focal point of the curved unit C defined by the curvature of the curved unit C, and hits the lower surface of the second reflection layer 20.

The light La which reaches the second reflection layer 20, is reflected on the lower surface of the second reflection layer 20 and then travels in a direction defined by the angle of the lower surface of the second reflection layer 20, penetrates the color filter layer 12, and ultimately reaches the light receiving unit 16. For example, when the rear surface of the second reflection layer 20 is parallel to the front surface of the color filter layer 12 and the front surface of the light receiving unit 16, the light La which is reflected on the second reflection layer 20 moves forward in the vertical direction with respect to the color filter layer 12, vertically penetrates the layer 12, moves forward in the vertical direction with respect to the light receiving unit 16, and is received by the light receiving unit 16.

In this manner, the first reflection layer 18 and the second reflection layer 20 (having, for example, a convex surface facing the first reflection layer 18) causes the light La which is incident on the front surface of the second planarization layer 21 from the vertical direction to be incident on the front surface of the color filter layer 12 and the light receiving unit 16 at a predetermined angle (for example, a vertical angle).

Next, as illustrated in FIG. 7B, when light Lb is incident on the second planarization layer 21 from the diagonal direction, the light Lb moves forward in the diagonal direction in the second planarization layer 21, and reaches the curved unit C of the first reflection layer 18. The light Lb reaches the curved unit C at an angle different from the incident angle on the curved unit C of the light La.

The light Lb which reaches the curved unit C is reflected on the front surface of the curved unit C, moves forward to be finally condensed at the focal point of the curved unit C, and reaches the rear surface of the second reflection layer 20. In other words, regardless of the incident angle of the light which is incident on the solid-state imaging device 10, the curved unit C reflects the light to condense the light at the focal point defined by the curvature of the curved unit C all the time.

The light Lb which reaches the second reflection layer 20 is reflected and moves forward in a direction defined by the angle of the second reflection layer 20, penetrates the color filter layer 12, and reaches the light receiving unit 16. For example, when the rear surface of the second reflection layer 20 is parallel to the front surface of the color filter layer 12 and the front surface of the light receiving unit 16, the light Lb which is reflected on the second reflection layer 20 moves forward in the vertical direction with respect to the color filter layer 12, vertically penetrates the layer 12, moves forward in the vertical direction with respect to the light receiving unit 16, and is received in the light receiving unit 16.

In this manner, the first reflection layer 18 and the second reflection layer 20 causes even the light Lb which is incident on the second planarization layer 21 from the diagonal direction to be incident on the color filter layer 12 and the light receiving unit 16 at the predetermined angle (for example, the vertical angle), similarly to a case where the light La is incident on the second planarization layer 21 from the vertical direction.

In this manner, according to the solid-state imaging device 10, the curved unit C of the first reflection layer 18 reflects the light which reaches the front surface of the curved unit C to make the light reach the focal point defined by the curvature of the curved unit C. Then, the second reflection layer 20 reflects the light reflected on the first reflection layer 18 in a direction defined by the surface shape (e.g., convex shape) of the second reflection layer 20. Therefore, regardless of the angle of the light which is incident on the solid-state imaging device 10, it is possible to cause the light to be incident on the color filter layer 12 and the light receiving unit 16 at the predetermined angle (for example, the vertical angle).

In addition, in the solid-state imaging device in the related art, a so-called scaling, in which a position of the light receiving unit is designed to be shifted only by a predetermined distance from right below of a micro lens which condenses the light, is performed. However, according to the solid-state imaging device of the present embodiment, regardless the angle of the light which is incident on the solid-state imaging device 10, since it is possible to cause the light to be incident on the color filter layer 12 and the light receiving unit 16 at the predetermined angle (for example, the vertical angle), the scaling is not required to be performed.

While example embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the above-described embodiment is a rear surface irradiation type solid-state imaging device 10. However, the exemplary embodiments can be similarly employed even in a so-called front surface irradiation type solid-state imaging device in which the color filter layer is provided via the wiring layer on the front surface which is the first surface of the semiconductor substrate.

What is claimed is:

1. A solid-state imaging device, comprising:
a semiconductor substrate that including a photodiode;
a color filter on a first surface of the semiconductor substrate in alignment with the photodiode, the color filter transmitting light within a predetermined wavelength band;
a first reflection layer on the color filter, the first reflection layer including a concave curved surface;
a supporting layer on; on the concave curved surface of the first reflection layer, the supporting layer being substantially transparent to light within the predetermined wavelength band;
a second reflection layer on the supporting layer at a position corresponding to a focal point of the concave curved surface of the first reflection layer for light having a wavelength within the predetermined wavelength band of the color filter;
a planarization layer on the second reflection layer and the first reflection layer; and
a microlens on the planarization layer, wherein
the supporting layer and the planarization layer are formed of a same resin material, and
the first reflection layer and the second reflection layer are made of materials that have a refractive index higher than a refractive index of the resin material.

2. The solid-state imaging device of claim 1, further comprising a plurality of photodiodes in a lattice arrangement.

3. The solid-state imaging device of claim 1, wherein the first reflection layer comprises aluminum.

4. The solid-state imaging device of claim 1, wherein the first reflection layer comprises copper.

5. The solid-state imaging device of claim 4, wherein the first reflection layer further comprises an aluminum layer disposed at the concave surface.

6. The solid-state imaging device of claim 1, wherein the second reflection layer includes a convex surface facing the first reflection layer.

7. The solid-state imaging device of claim 1, wherein the second reflection layer is angled with respect to the semiconductor substrate.

8. A solid-state imaging device, comprising:
a semiconductor substrate that is provided with a light receiving unit;
a spectral unit that is provided on the light receiving unit on a first surface of the semiconductor substrate, and allows light having a predetermined wavelength band to penetrate;
a first reflection layer that includes a curved unit provided on the spectral unit;
a transparent supporting layer that is provided on a front surface of the curved unit of the first reflection layer; and
a second reflection layer that is provided on the supporting layer.

9. The solid-state imaging device of claim 8, wherein the first reflection layer and the second reflection layer are made of a material that has a refractive index higher than a refractive index of the supporting layer.

10. The solid-state imaging device of claim 9, wherein the second reflection layer is provided at a position that coincides with a focal point of the curved unit with respect to light having a wavelength that coincides with a transmission wavelength of the spectral unit.

11. The solid-state imaging device of claim 8, wherein the second reflection layer is provided at a position that coincides with a focal point of the curved unit with respect to light having a wavelength that coincides with a transmission wavelength of the spectral unit.

12. The solid-state imaging device of claim 8, wherein
a planarization layer is provided on the front surface of the first reflection layer to surround the second reflection layer,
the supporting layer is a same transparent resin layer as the planarization layer, and
a region of the planarization layer above the light receiving unit is formed into a microlens.

13. The solid-state imaging device of claim 8, wherein the first reflection layer comprises aluminum.

14. The solid-state imaging device of claim 8, wherein the first reflection layer comprises copper.

15. The solid-state imaging device of claim 14, wherein the first reflection layer further comprises an aluminum layer disposed on the concave surface.

16. The solid-state imaging device of claim 8, wherein the second reflection layer includes a convex surface facing the first reflection layer

17. The solid-state imaging device of claim 8, wherein the second reflection layer is angled with respect to the semiconductor substrate.

18. A method of manufacturing a solid-state imaging device, the method comprising:
forming a photodiode in a semiconductor substrate;
forming a color filter on a first surface of the semiconductor substrate in alignment with the photodiode, the color filter transmitting light within a predetermined wavelength band;
forming a first reflection layer on the color filter, the first reflection layer including a concave curved surface;
forming supporting layer on the concave curved surface of the first reflection layer, the supporting layer being substantially transparent to light within the predetermined wavelength band;
forming a second reflection layer on the supporting layer at a position corresponding to a focal point of the concave curved surface of the first reflection layer for light having a wavelength within the predetermined wavelength band of the color filter;
forming a planarization layer on the second reflection layer and the first reflection layer; and
forming a microlens on the planarization layer, wherein
the supporting layer and the planarization layer are formed of a same resin material, and
the first reflection layer and the second reflection layer are made of materials that have a refractive index higher than a refractive index of the resin material.

19. The method of claim 17, wherein the first reflection layer comprises aluminum.

20. The method of claim 17, wherein the second reflection layer includes a convex surface facing the first reflection layer.
